(19) United States
(12) Patent Application Publication
(10) Pub. No.: US 2024/0117489 A1
(43) Pub. Date: Apr. 11, 2024

(54) HALOGEN-RESISTANT THERMAL BARRIER COATING FOR PROCESSING CHAMBERS

(71) Applicant: Applied Materials, Inc., Santa Clara, CA (US)

(72) Inventors: Amir H. TAVAKOLI, San Jose, CA (US); Ala MORADIAN, Sunnyvale, CA (US); Tetsuya ISHIKAWA, San Jose, CA (US)

(21) Appl. No.: 17/961,553

(22) Filed: Oct. 6, 2022

(51) Int. Cl. C23C 16/44

(52) U.S. Cl. CPC C23C 16/4404

(57) ABSTRACT

A coating on a processing chamber component includes a metallic bond layer deposited on a surface of the component. A thermal barrier layer is deposited on the bond layer. A substantially non-porous ceramic sealing layer is deposited on the thermal barrier layer. The sealing layer substantially conforms to irregularities of the surface of the thermal barrier layer. A chemistry of the sealing layer is selected for resistance to attack from halogen-containing chemicals.

### BACKGROUND

### Field

Embodiments of the present disclosure generally relate to chambers used for processing substrates, such as in the manufacture of electronic devices. In particular, the present disclosure concerns coatings applied to chamber components. The coatings hinder heat transfer to the chamber components, and provide corrosion and erosion protection.

### Description of the Related Art

The processing of substrates is typically performed in chambers, in which the substrates are exposed to heat and reactive chemicals. In some processing operations, the chemicals may be present in the form of a plasma. Cleaning operations typically involve exposure of the processing chambers to corrosive chemicals, such as hydrochloric acid, at elevated temperatures. The processing and the cleaning environments—including corrosive chemicals and plasma—can be detrimental to the processing chambers and the ancillary equipment therein. Additionally, temperature gradients across substrates undergoing processing, such as caused by heat transfer through the walls of the processing chambers, can adversely affect the uniformity of substance deposition on substrates, and hence impact the quality of the finished product.

Thus, there is a need for improved systems and processes that mitigate the above issues.

### SUMMARY

The present disclosure relates to coatings suitable for components used in chambers for processing substrates. In one implementation, a substrate processing chamber component includes a metal body. The component includes a metallic bond layer deposited on a surface of the metal body. The component further includes a thermal barrier layer deposited on the bond layer, and a substantially non-porous ceramic sealing layer deposited on the thermal barrier layer.

In another implementation, a substrate processing chamber component includes a body that includes a stainless steel. The component includes a metallic bond layer of a first thickness deposited on a surface of the body. The bond layer has a corrosion resistance to halogen-containing chemicals greater than a corrosion resistance of the body to halogen-containing chemicals. The component further includes a thermal barrier layer of a second thickness deposited on the bond layer. The second thickness is greater than the first thickness. The component further includes a substantially non-porous ceramic sealing layer of a third thickness deposited on the thermal barrier layer. The third thickness is less than the first thickness.

In another implementation, a substrate processing chamber component includes a metal body. The component includes a metallic bond layer deposited on a surface of the metal body, a thermal barrier layer deposited on the bond layer, and a ceramic sealing layer deposited on the thermal barrier layer. The ceramic sealing layer includes a first sublayer including a first ceramic, a second sublayer including a second ceramic, and a third sublayer including a third ceramic. The second ceramic is of a different chemical composition to the first and third ceramics.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, as the disclosure may admit to other equally effective embodiments.

FIG. 1 schematically illustrates a processing chamber.

FIG. 2 schematically illustrates aspects of a coating applied to one or more components of the processing chamber of FIG. 1.

FIG. 3 schematically illustrates an embodiment of a portion of the coating of FIG. 2.

FIGS. 4A-4C schematically illustrate embodiments of a portion of the coating of FIG. 2.

FIGS. 4D and 4E schematically illustrate how the morphology, porosity, and magnitude of open porosity of a ceramic layer can be related to the technique used to deposit the ceramic.

FIGS. 4F and 4G schematically illustrate embodiments of a portion of the coating of FIG. 2.

FIGS. 5A to 5E schematically illustrate embodiments of a portion of the coating of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to chambers used for processing substrates, such as in the manufacture of electronic devices. More specifically, the present disclosure relates to coatings suitable for chamber components, such as chamber walls, susceptor supports, gas delivery fittings, gas exhaust fittings, and the like. The coatings hinder heat transfer to the chamber components, and provide corrosion and erosion protection.

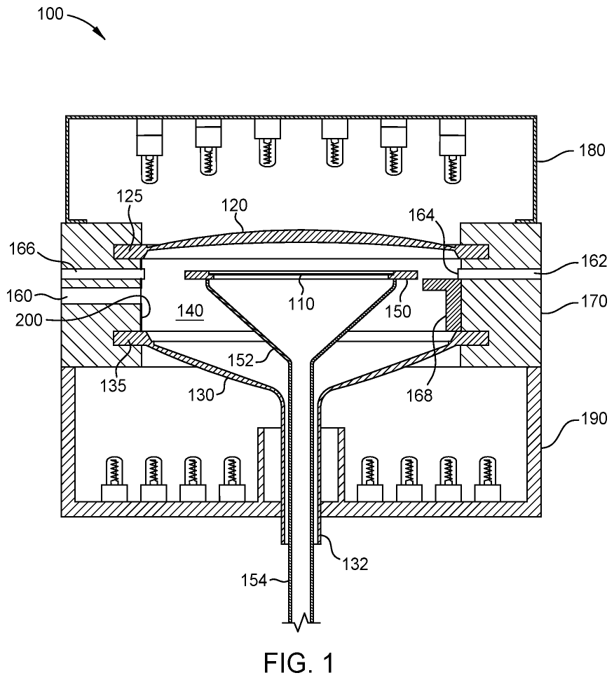

FIG. 1 schematically illustrates a processing chamber 100. Processing chamber 100 includes an upper heating module 180 above a chamber body 170, and a lower heating module 190 below the chamber body 170.

Processing chamber 100 may be a processing chamber for performing any thermal process, such as an epitaxial process. It is contemplated that the processing chamber 100 may be used to process a substrate, including the deposition of a material on a surface of the substrate. It is contemplated that while a processing chamber for an epitaxial process is shown and described, the concept of the present disclosure is also applicable to other processing chambers capable of providing a controlled thermal cycle that heats the substrate for processes such as, for example, thermal annealing, thermal cleaning, thermal chemical vapor deposition, thermal oxidation and thermal nitridation. It is further contemplated that the embodiments of the present disclosure may be applied to components of other types of processing chambers, such as processing chambers configured to perform processing operations involving plasma, such as etching and/or plasma-enhanced chemical vapor deposition.

Referring to FIG. 1, the chamber body 170 includes an upper window 120 and a lower window 130 with a processing volume 140 therebetween. The processing volume 140 is substantially cylindrical. The upper window 120 includes a base 125 secured in the chamber body 170, and the lower window 130 includes a base 135 secured in the chamber body 170. A neck 132 coupled to the lower window 130 is disposed about a shaft 154 of a susceptor support 152. The susceptor support 152 carries a susceptor 150, upon which a substrate 110 can be positioned within the processing volume 140.

It is contemplated that the susceptor 150 may be made of silicon carbide-coated graphite. A motor (not shown) rotates the shaft 154 of the susceptor support 152 about the longitudinal axis of the shaft 154, and thus rotates the susceptor 150, and the substrate 110. The substrate 110 is brought into the chamber body 170 through a loading port 160 and positioned on the susceptor 150.

The processing chamber 100 includes one or more gas inlets 162. Each gas inlet 162 includes a nozzle 164. The processing chamber 100 includes one or more gas exhaust fittings 166. The processing chamber 100 includes one or more liners 168 within the processing volume 140.

One or more components of the processing chamber 100 exposed in the processing volume 140 is coated with a coating 200. It is contemplated that the coating 200 may be applied to metallic components of the processing chamber 100 exposed in the processing volume 140. Examples of metallic components that may be coated with the coating 200 include the walls of the chamber body 170, the susceptor support 152, the shaft 154, the gas inlet(s) 162, the nozzle(s) 164, the gas exhaust fitting(s) 166, the liner 168, and the like. In some embodiments, the base 125 of the upper window 120 and/or the base 135 of the lower window 130 includes a metallic component that may be coated with the coating 200.

In other processing chambers, such as processing chambers configured to perform processing operations involving plasma, exemplary metallic components that may be coated with the coating 200 include chamber body floor, lid, and walls; substrate support structures; liners; gas exhaust fittings; and gas delivery fittings, such as showerheads, gas distribution plates, plenum walls, and the like.

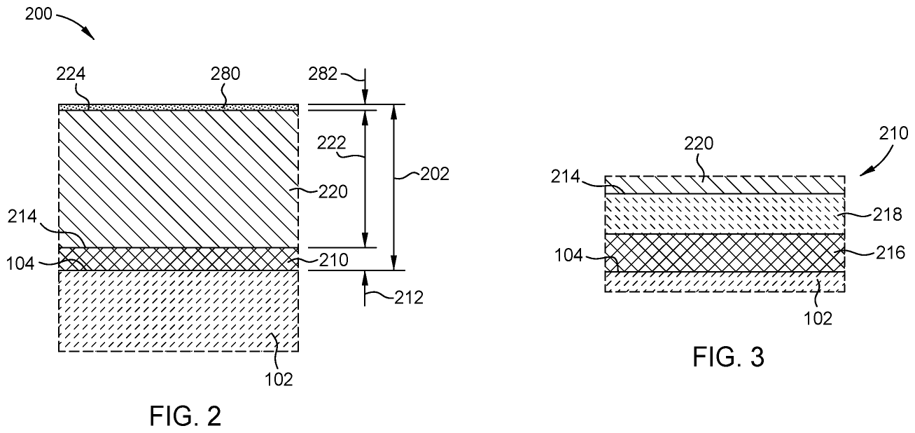

FIG. 2 schematically illustrates aspects of the coating 200 in cross section. FIG. 2 shows the coating 200 applied to a surface 104 of a metal body 102. The metal body 102 represents any metal structure, such as described above, that can be part of, or used within, a processing chamber, such as processing chamber 100. Examples of metals on which the coating 200 may be applied include aluminum and steel, such as a stainless steel, such as 316L.

A thickness 202 of the coating 200 is from about 0.5 mm to about 10 mm. For example, the thickness 202 of the coating 200 may be from 1 mm to 10 mm, such as 1.5 mm to 10 mm, 1.5 mm to 9 mm, 1.5 mm to 8 mm, 2 mm to 8 mm, 2.5 mm to 8 mm, 2.5 mm to 7 mm, 3 mm to 7 mm, 3.5 mm to 7 mm, 3.5 mm to 6 mm, 4 mm to 6 mm, 4.5 mm to 6 mm, or 5 mm to 6 mm. Other thicknesses are also contemplated.

The coating 200 includes three layers. A bond layer 210 is on the surface 104 of the metal body 102. A thermal barrier layer 220 is on the bond layer 210. A sealing layer 280 is on the thermal barrier layer 220.

The bond layer 210 is metallic. In some embodiments which may be combined with other embodiments, the bond layer 210 is a pure metal, such as pure nickel or pure titanium. It is contemplated that the pure metal may have a purity of at least 99%, such as at least 99.5%, at least 99.6%, at least 99.7%, at least 99.8%, or at least 99.9%. In some embodiments, the bond layer 210 is an alloy, such as a cobalt-based alloy, an iron-based alloy, a nickel-based alloy, or a titanium-based alloy. In some embodiments, the bond layer 210 includes a composite of ceramic particulates distributed in a metal matrix. In an example, the metal matrix is nickel, and the ceramic particulates are a metal oxide. In some embodiments, the addition of the ceramic particulates to the metal matrix adjusts a thermal expansion coefficient of the bond layer 210. In some embodiments, the addition of the ceramic particulates to the metal matrix promotes adhesion of the bond layer 210 to the thermal barrier layer 220.

In some embodiments which may be combined with other embodiments, the metal of the bond layer 210 is selected at least in part on the basis that a thermally grown oxide layer will form on the bond layer 210 during use of the metal body 102 when processing a substrate, such as substrate 110. In some embodiments which may be combined with other embodiments, the metal of the bond layer 210 is selected at least in part on the basis that a thermally grown oxide layer will not form on the bond layer 210 during use of the metal body 102 when processing a substrate, such as substrate 110.

The bond layer 210 has a corrosion resistance to halogen-containing chemicals greater than a corrosion resistance of the metal body 102 to halogen-containing chemicals. Examples of such halogen-containing chemicals include halogen acids (for example: hydrochloric acid, hydrofluoric acid, or the like), halogen gases (for example: chlorine, fluorine, bromine, chlorofluorides, or the like), gaseous halides (for example: chlorine trifluoride, carbon tetrafluoride, nitrogen trifluoride, or the like), and plasmas containing such halogen acids, halogen gases, or gaseous halides.

In some embodiments which may be combined with other embodiments, the bond layer 210 has a coefficient of thermal expansion less than a coefficient of thermal expansion of the metal body 102, and greater than or equal to a coefficient of thermal expansion of the thermal barrier layer 220. In an example, the bond layer 210 has a coefficient of thermal expansion greater than or equal to a coefficient of thermal expansion of the portion of the thermal barrier layer 220 that is adjacent to the bond layer 210.

A thickness 212 of the bond layer 210 is from about 50 microns to about 500 microns. For example, the thickness 212 of the bond layer 210 may be from 50 microns to 450 microns, such as 50 microns to 400 microns, 50 microns to 300 microns, 50 microns to 200 microns, or 50 microns to 100 microns. Other thicknesses are also contemplated.

The bond layer 210 can be substantially non-porous. In an example, the bond layer 210 has a porosity of 0.1% or less, such as 0.05% or less, 0.01% or less, or 0%. In some embodiments which may be combined with other embodiments, the bond layer 210 has a porosity greater than 0.1%, such as up to 10%. In an example, the bond layer 210 has a porosity of 0.5% to 10%, such as 1% to 9%, 1.5% to 8%, 2% to 7%, 2.5% to 6%, or 3% to 5%. In some embodiments which may be combined with other embodiments, the bond layer 210 has a porosity that increases with distance away from the surface 104 of the metal body 102. In an example, the bond layer 210 has a porosity of 0.1% or less at the surface 104, and the porosity increases to 3% away from the surface 104.

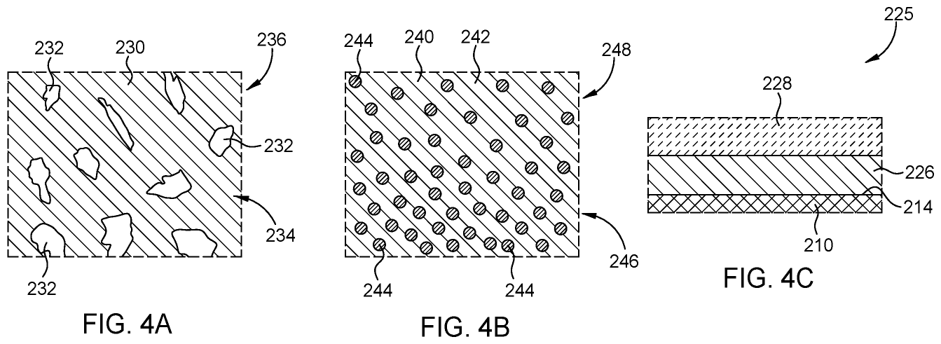

The bond layer 210 is deposited onto the surface 104 of the metal body 102 by a thermal spray technique, such as air plasma spray (APS) or high velocity oxy-fuel. In some embodiments which may be combined with other embodiments, the bond layer 210 is deposited as a single layer onto the surface 104. However, in some embodiments, the bond layer 210 is deposited as a plurality of sublayers onto the surface 104. For example, as shown schematically in FIG. 3, in some embodiments, the bond layer 210 includes a first sublayer 216 on the surface 104 of the metal body 102, and a second sublayer 218 on the first sublayer 216. In some embodiments, the first sublayer 216 and the second sublayer 218 are formed by the same thermal spray technique. In some embodiments, the first sublayer 216 and the second sublayer 218 are formed by different thermal spray techniques.

The first sublayer 216 and the second sublayer 218 may be formed of the same metal. Alternatively, the first sublayer 216 and the second sublayer 218 may not formed of the same metal. In an example, the first sublayer 216 may be formed of pure nickel, and the second sublayer 218 may be formed of a nickel-based alloy.

In some embodiments which may be combined with other embodiments, the first sublayer 216 and the second sublayer 218 have substantially the same porosity. Alternatively, the first sublayer 216 and the second sublayer 218 do not have the same porosity. In an example, the first sublayer 216 may be substantially non-porous, and the second sublayer 218 may have a porosity greater than 0.1%, such as described above.

Returning to FIG. 2, the thermal barrier layer 220 is on a surface 214 of the bond layer 210. The thermal barrier layer 220 includes a ceramic material. The ceramic material includes one or more of a metal oxide, a metal nitride, a metal oxynitride, or a metal oxycarbide. It is contemplated that such compounds include corresponding metalloid compounds, such as silicon oxides, and the like. Exemplary ceramic materials of the thermal barrier layer 220 include magnesium silicates, zirconia, yttria-stabilized zirconia, hafnia, gadolinia-stabilized hafnia, rare-earth zirconates, and silicon oxynidrides.

A thickness 222 of the thermal barrier layer 220 is from about 0.5 mm to about 10 mm. For example, the thickness 222 of the thermal barrier layer 220 may be from 1 mm to 10 mm, such as 1.5 mm to 10 mm, 1.5 mm to 9 mm, 1.5 mm to 8 mm, 2 mm to 8 mm, 2.5 mm to 8 mm, 2.5 mm to 7 mm, 3 mm to 7 mm, 3.5 mm to 7 mm, 3.5 mm to 6 mm, 4 mm to 6 mm, 4.5 mm to 6 mm, or 5 mm to 6 mm.

The thermal barrier layer 220 has an overall thermal conductivity of less than or equal to 20 W/m·K. For example, the overall thermal conductivity of the thermal barrier layer 220 may be less than or equal to 18 W/m·K, 16 W/m·K, 14 W/m·K, 12 W/m·K, 10 W/m·K, 8 W/m·K, 6 W/m·K, or 4 W/m·K. Furthermore, the overall thermal conductivity of the thermal barrier layer 220 may be 0.5 W/m·K to 20 W/m·K, such as 1 W/m·K to 20 W/m·K, 2 W/m·K to 20 W/m·K, 3 W/m·K to 18 W/m·K, 4 W/m·K to 16 W/m·K, 5 W/m·K to 14 W/m·K, 6 W/m·K to 12 W/m·K, or 7 W/m·K to 10 W/m·K.

The thermal barrier layer 220 is deposited onto the surface 214 of the bond layer 210 by a thermal spray technique, such as APS. It is contemplated that the thermal barrier layer 220 may additionally or alternatively be deposited onto the surface 214 of the bond layer 210 by a vapor deposition technique, such as electron beam physical vapor deposition (EB-PVD). In some embodiments which may be combined with other embodiments, the thermal barrier layer 220 is deposited onto the surface 214 of the bond layer 210 by a thermal spray technique in combination with a vapor deposition technique.

The thermal barrier layer 220 is deposited as a single layer onto the surface 214 of the bond layer 210. Alternatively, in some embodiments which may be combined with other embodiments, the thermal barrier layer 220 is deposited in multiple sublayers onto the surface 214 of the bond layer 210. In some embodiments, the single layer or any one or more of the multiple sublayers may be of a uniform composition. The single layer or any one or more of the multiple sublayers may be of a uniform morphology. Alternatively, the single layer or any one or more of the multiple sublayers may be of a single phase. The single layer or any one or more of the multiple sublayers may be doped with a secondary ceramic, such as a silicon oxide or a hafnium oxide. In some embodiments which may be combined with other embodiments, the single layer or any one or more of the multiple sublayers may be undoped.

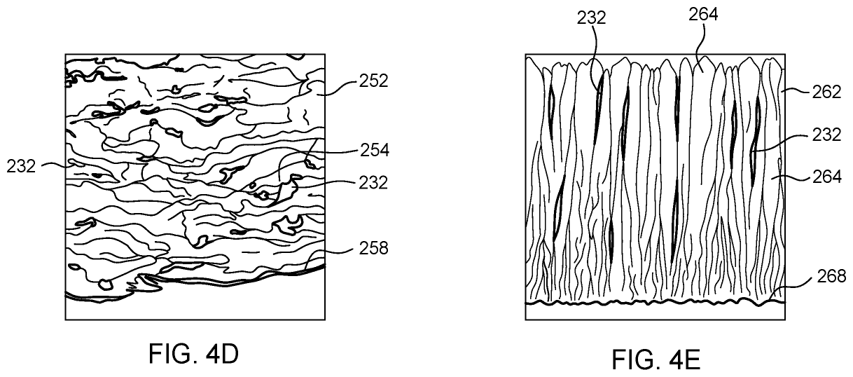

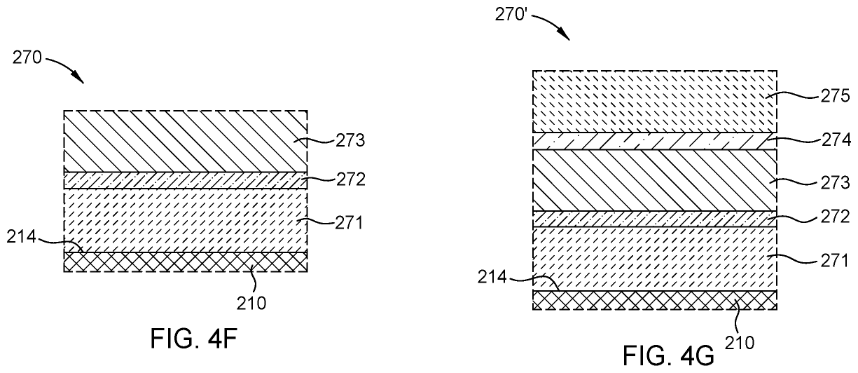

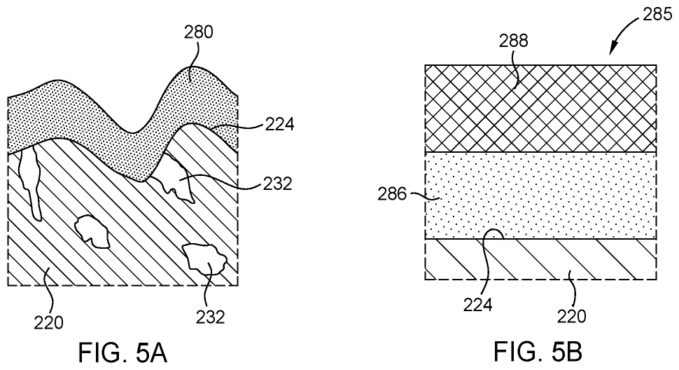

The single layer or any one or more of the multiple sublayers may be functionally graded. FIG. 4A schematically illustrates an exemplary functionally graded layer. Layer 230 represents a single layer or a sublayer of the thermal barrier layer 220. The layer 230 contains pores 232. In a first portion 234 of the layer 230, the pores 232 are more numerous and/or larger than the pores 232 in a second portion 236 of the layer 230. The porosity varies from a higher magnitude in the first portion 234 to a lower magnitude in the second portion 236. The locations of the first and second portions 234, 236 differ in proximity to the surface 104 of the metal body 102. In an example, the second portion 236 is further from the surface 104 of the metal body 102 than the first portion 234. Alternatively, the first portion 234 may be further from the surface 104 of the metal body 102 than the second portion 236.

FIG. 4B schematically illustrates another exemplary functionally graded layer. Layer 240 is a compositionally graded layer that represents a single layer or a sublayer of the thermal barrier layer 220. The layer 240 is a single phase ceramic that includes a first ceramic material 242 doped with a second ceramic material 244. An example single phase ceramic is yttria-stabilized zirconia (YSZ) in which the first ceramic material 242 is zirconia and the second ceramic material is yttria 244. In a first portion 246 of the layer 240, a proportion of the second ceramic material 244 is greater than in a second portion 248 of the layer 240. In the example of YSZ, the proportion of yttria in the first portion 246 can be from about 8% to about 20%, and the proportion of yttria in the second portion 248 can be from about 0% to about 8%. The second portion 248 is further from the surface 104 of the metal body 102 than the first portion 246. Alternatively, the first portion 246 may be further from the surface 104 of the metal body 102 than the second portion 248.

FIG. 4C schematically illustrates another exemplary functionally graded layer in which the thermal barrier layer 220 includes multiple sublayers in a laminated ceramic structure 225. Although only two sublayers are shown, it is contemplated that the laminated ceramic structure 225 of the thermal barrier layer 220 may include three, four, five, six, seven, or more sublayers. When more than two sublayers are present, it is contemplated that any two sublayers may have the same chemical composition, porosity, porosity distribution, or morphology. It is further contemplated that the laminated ceramic structure 225 of the thermal barrier layer 220 may include a repeating pattern of multiple pairs of two sublayers. In such examples, it is further contemplated that any pair of two sublayers may have the same chemical composition, porosity, porosity distribution, or morphology.

As shown in FIG. 4C, the laminated ceramic structure 225 of the thermal barrier layer 220 includes a first sublayer 226 on the surface 214 of the bond layer 210, and a second sublayer 228 on the first sublayer 226. Each of the first sublayer 226 and the second sublayer 228 is made of ceramic material. The first sublayer 226 and the second sublayer 228 may have the same chemical composition. The first sublayer 226 and the second sublayer 228 may be formed by the same deposition technique or by different deposition techniques. The ceramic of the first sublayer 226 may differ from the ceramic of the second sublayer 228 in at least one of: chemical composition, porosity, magnitude of open porosity, or morphology.

FIGS. 4D and 4E schematically illustrate how the morphology, porosity, and magnitude of open porosity of a ceramic layer can be related to the technique used to deposit the ceramic. FIG. 4D is a representation of a micrograph showing a ceramic material 252 deposited by APS onto a surface 258. Many of the pores 232 are surrounded by grains 254 of ceramic material 252; much of the pore volume is represented as so-called “closed porosity.” Only a few of the pores 232 are open to the exposed surface 256 of the ceramic material 252; less of the pore volume is represented as so-called “open porosity” than as closed porosity.

FIG. 4E is a representation of a micrograph showing a ceramic material 262 deposited by EB-PVD onto a surface 268. Only a few of the pores 232 are surrounded by grains 264 of ceramic material 262; much of the pore volume is represented as open porosity. Many of the pores 232 are open to the exposed surface 266 of the ceramic material 262; less of the pore volume is represented as closed porosity than as open porosity.

FIGS. 4D and 4E demonstrate examples in which the morphology of the ceramic material 252 of FIG. 4D is different from the morphology of the ceramic material 262 of FIG. 4E. In FIG. 4D, the grains 254 of ceramic material 252 tend to lie substantially parallel to the surface 258 upon which the ceramic material 262 is deposited. In contrast to the ceramic material 252 of FIG. 4D, the grains 264 of ceramic material 262 in FIG. 4E tend to lie substantially perpendicular to the surface 268 upon which the ceramic material 262 is deposited.

With further reference back to FIG. 4C, in embodiments in which the ceramic of the first sublayer 226 differs from the ceramic of the second sublayer 228, as described above, it is contemplated that the first sublayer 226 may be deposited using one deposition technique, and the second sublayer 228 is deposited using a different deposition technique. For example, the first sublayer 226 may be deposited using one of APS or EB-PVD, and the second sublayer 228 may be deposited using the other of APS or EB-PVD.

FIGS. 4F and 4G schematically illustrate examples in which the thermal barrier layer 220 includes a laminated metal-ceramic structure 270, 270′. In FIG. 4F, a first ceramic sublayer 271 is deposited on the surface 214 of the bond layer 210 A first metallic sublayer 272 is deposited on the first ceramic sublayer 271. A second ceramic sublayer 273 is deposited on the first metallic sublayer 272. The first ceramic sublayer 271 and the second ceramic sublayer 273 may have the same chemical composition. The first ceramic sublayer 271 and the second ceramic sublayer 273 may be formed by the same deposition technique or by different deposition techniques. In some embodiments which may be combined with other embodiments, the first ceramic sublayer 271 differs from the second ceramic sublayer 27 in at least one of: chemical composition, porosity, magnitude of open porosity, or morphology.

In some embodiments which may be combined with other embodiments, the first metallic sublayer 272 has a chemical composition that is similar to the bond layer 210. In some embodiments, the first metallic sublayer 272 has a structure that is similar to the bond layer 210. In one example, the first metallic sublayer 272 is a pure metal, such as pure nickel or pure titanium. It is contemplated that the pure metal may have a purity of at least 99%, such as at least 99.5%, at least 99.6%, at least 99.7%, at least 99.8%, or at least 99.9%. In some embodiments which may be combined with other embodiments, the first metallic sublayer 272 is an alloy, such as a cobalt-based alloy, an iron-based alloy, a nickel-based alloy, or a titanium-based alloy. The metal of the first metallic sublayer 272 is selected at least in part on the basis that a thermally grown oxide layer will form on the first metallic sublayer 272 during use of the metal body 102 when processing a substrate, such as substrate 110. Alternatively, the metal of the first metallic sublayer 272 may be selected at least in part on the basis that a thermally grown oxide layer will not form on the first metallic sublayer 272 during use of the metal body 102 when processing a substrate, such as substrate 110.

In FIG. 4G, the laminated metal-ceramic structure 270′ includes additional sublayers deposited onto the laminated metal-ceramic structure 270 of FIG. 4F. FIG. 4G shows a second metallic sublayer 274 deposited on the second ceramic sublayer 273. A third ceramic sublayer 275 is deposited on the second metallic sublayer 274. In some embodiments which may be combined with other embodiments, the third ceramic sublayer 275 and at least one of the first ceramic sublayer 271 or the second ceramic sublayer 273 have the same chemical composition. The third ceramic sublayer 275 and at least one of the first ceramic sublayer 271 or the second ceramic sublayer 273 are formed by the same deposition technique or by different deposition techniques. In some embodiments which may be combined with other embodiments, the third ceramic sublayer 275 differs from the first ceramic sublayer 271 in at least one of: chemical composition, porosity, magnitude of open porosity, or morphology. In some embodiments, the third ceramic sublayer 275 differs from the second ceramic sublayer 273 in at least one of: chemical composition, porosity, magnitude of open porosity, or morphology.

The second metallic sublayer 274 may have a chemical composition or structure that is similar to the bond layer 210. Additionally or alternatively, the second metallic sublayer 274 has a chemical composition that is similar to the first metallic sublayer 272, and/or the second metallic sublayer 274 has a structure that is similar to the first metallic sublayer 272. The second metallic sublayer 274 is a pure metal, such as pure nickel or pure titanium. It is contemplated that the pure metal may have a purity of at least 99%, such as at least 99.5%, at least 99.6%, at least 99.7%, at least 99.8%, or at least 99.9%. Alternatively, the second metallic sublayer 274 may be an alloy, such as a cobalt-based alloy, an iron-based alloy, a nickel-based alloy, or a titanium-based alloy. The metal of the second metallic sublayer 274 is selected at least in part on the basis that a thermally grown oxide layer will form on the second metallic sublayer 274 during use of the metal body 102 when processing a substrate, such as substrate 110. However, the metal of the second metallic sublayer 274 may be selected at least in part on the basis that a thermally grown oxide layer will not form on the second metallic sublayer 274 during use of the metal body 102 when processing a substrate, such as substrate 110.

It is contemplated that the laminated metal-ceramic structure 270′ of FIG. 4G may include further additional metallic and ceramic sublayers. In an example, the laminated metal-ceramic structure 270′ includes one or more pairs of additional sublayers on top of the third ceramic sublayer 275, each pair including a metallic sublayer and a ceramic sublayer on top of the metallic sublayer.

Returning to FIG. 2, the sealing layer 280 is on a surface 224 of the thermal barrier layer 220. The sealing layer 280 inhibits ingress of chemicals, such as gases, into the pores 232 of the thermal barrier layer 220. The sealing layer 280 includes a ceramic material. The ceramic material includes one or more of a metal oxide, a metal fluoride, or a metal oxyfluoride. It is contemplated that such compounds include corresponding metalloid compounds, such as silicon oxides, and the like. Exemplary ceramic materials of the sealing layer 280 include silica, hafnia, zirconia, yttria, magnesium fluoride, yttrium fluoride, lanthanum fluoride, and yttrium oxyfluoride.

The sealing layer 280 is resistant to chemical attack by halogen-containing chemicals. Examples of such halogen-containing chemicals include halogen acids (for example: hydrochloric acid, hydrofluoric acid, or the like), halogen gases (for example: chlorine, fluorine, bromine, chlorofluorides, or the like), gaseous halides (for example: chlorine trifluoride, carbon tetrafluoride, nitrogen trifluoride, or the like), and plasmas containing such halogen acids, halogen gases, or gaseous halides.

The chemistry and/or the structure of the sealing layer 280 is selected according to the chemistry of cleaning gases and/or processing gases to be used in a processing chamber such as the processing chamber 100. In an example, for applications in which chlorine gas is to be used for cleaning the processing chamber, the sealing layer 280 may include silica. In another example, for applications in which a chlorofluoride gas is to be used for cleaning the processing chamber, the sealing layer 280 may include a ceramic containing hafnium. In a further example, for applications in which a gas rich in fluorine is to be used for cleaning the processing chamber, the sealing layer 280 may include a ceramic containing yttrium and/or a metal fluoride and/or a metal oxyfluoride. In further examples, the sealing layer 280 may include one or more of silica, hafnia, zirconia, yttria, magnesium fluoride, yttrium fluoride, lanthanum fluoride, or yttrium oxyfluoride.

A thickness 282 of the sealing layer 280 is from about 0.05 microns to about 10 microns. For example, the thickness 282 of the sealing layer 280 may be from 0.1 microns to about 10 microns, such as 0.1 microns to 9 microns, 0.1 microns to 8 microns, 0.1 microns to 7 microns, 0.1 microns to 6 microns, 0.1 microns to 5 microns, 0.1 microns to 4 microns, 0.1 microns to 3 microns, 0.1 microns to 2 microns, or 0.1 microns to 1 micron.

The sealing layer 280 is substantially non-porous. In an example, the sealing layer 280 has a porosity of 0.1% or less, such as 0.05% or less, 0.01% or less, or 0%.

The sealing layer 280 is deposited onto the surface 224 of the thermal barrier layer 220 by a physical vapor deposition (PVD) technique, such as ion assisted deposition, magnetron sputtering, or ion beam sputtering. Additionally or alternatively, the sealing layer 280 may be deposited onto the surface 224 of the thermal barrier layer 220 by a chemical vapor deposition (CVD) technique, such as atomic layer deposition. In some embodiments, the sealing layer 280 is deposited onto the surface 224 of the thermal barrier layer 220 by a PVD technique in combination with a CVD technique.

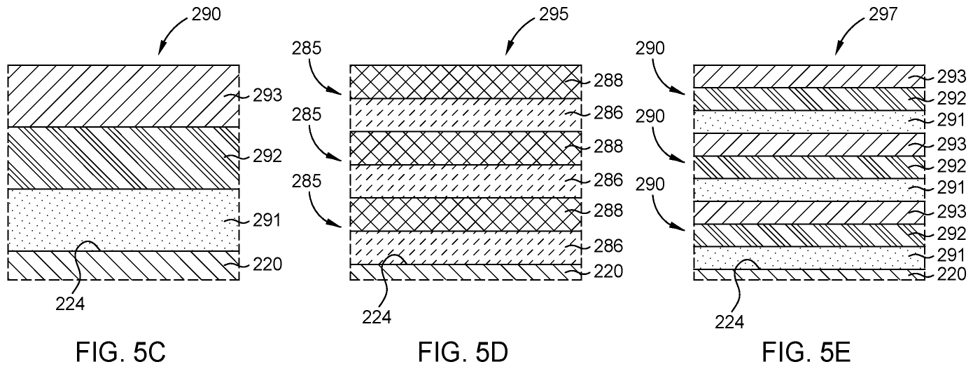

FIGS. 5A to 5E schematically illustrate aspects of the sealing layer 280. FIG. 5A shows the surface 224 of the thermal barrier layer 220 to be irregular. The thermal barrier layer 220 includes pores 232, some of which are open at the surface 224. The sealing layer 280 is conformally deposited on the thermal barrier layer 220 such that the sealing layer 280 conforms to the irregularities of the surface 224 of the thermal barrier layer 220. As illustrated, it is contemplated that the sealing layer 280 may bridge over the pores 232 that are open at the surface 224 of the thermal barrier layer 220. In some embodiments, the sealing layer 280 may at least partially penetrate into the pores 232 that are open at the surface 224 of the thermal barrier layer 220.

The sealing layer 280 may deposited as a single layer or multiple sublayers onto the surface 224 of the thermal barrier layer 220. The single layer or any one or more of the multiple sublayers may be of a uniform composition and/or of a uniform morphology.

In some embodiments which may be combined with other embodiments, the single layer or any one or more of the multiple sublayers may be functionally graded and/or compositionally graded. FIG. 5B schematically illustrates an exemplary structure 285 of the sealing layer 280. The structure 285 is functionally graded and/or compositionally graded, and has a coefficient of thermal expansion less than or equal to a coefficient of thermal expansion of the underlying thermal barrier layer 220. The structure 285 includes a first sublayer 286 on the surface 224 of the thermal barrier layer 220, and a second sublayer 288 on the first sublayer 286. Each of the first sublayer 286 and the second sublayer 288 is made of ceramic material, such as a ceramic material selected from the examples of ceramic materials listed above.

The first sublayer 286 and the second sublayer 288 have different chemical compositions. In an example, one of the first sublayer 286 or the second sublayer 288 is silica, and the other of the first sublayer 286 or the second sublayer 288 is hafnia. In another example, one of the first sublayer 286 or the second sublayer 288 is zirconia, and the other of the first sublayer 286 or the second sublayer 288 is yttria. In a further example, one of the first sublayer 286 or the second sublayer 288 is hafnia, and the other of the first sublayer 286 or the second sublayer 288 is yttria.

FIG. 5C schematically illustrates another exemplary structure 290 of the sealing layer 280. In some embodiments, the structure 290 is functionally graded and/or compositionally graded. In some embodiments which may be combined with other embodiments, the structure 290 has a coefficient of thermal expansion less than or equal to a coefficient of thermal expansion of the underlying thermal barrier layer 220. The structure 290 includes a first sublayer 291 on the surface 224 of the thermal barrier layer 220, a second sublayer 292 on the first sublayer 291, and a third sublayer 293 on the second sublayer 292. Each of the first sublayer 286, the second sublayer 288, and the third sublayer 293 is made of ceramic material, such as a ceramic material selected from the examples of ceramic materials listed above. The first sublayer 286, the second sublayer 288, and the third sublayer 293 have different chemical compositions.

FIG. 5D schematically illustrates another exemplary structure 295 of the sealing layer 280. In some embodiments which may be combined with other embodiments, the structure 295 is functionally graded and/or compositionally graded. The structure 295 is a laminated structure, such as a nanolaminate, including a stack of multiples of the structure 285 of FIG. 5B in which a first sublayer 286 of one structure 285 is deposited on a second sublayer 288 of another structure 285. In some embodiments which may be combined with other embodiments, a thickness of any one or more of the first sublayer 286 or the second sublayer 288 in any structure 285 of the structure 295 is less than or equal to 50 nm, such as less than or equal to 40 nm, 30 nm, 20 nm, 15 nm, 10 nm, or 5 nm. In some embodiments which may be combined with other embodiments, a morphology of any one or more of the first sublayer 286 or the second sublayer 288 in any structure 285 of the structure 295 changes with increasing thickness.

FIG. 5E schematically illustrates another exemplary structure 297 of the sealing layer 280. In some embodiments which may be combined with other embodiments, the structure 297 is functionally graded and/or compositionally graded. The structure 297 is a laminated structure, such as a nanolaminate, including a stack of multiples of the structure 290 of FIG. 5C in which a first sublayer 291 of one structure 290 is deposited on a third sublayer 293 of another structure 290. In some embodiments which may be combined with other embodiments, a thickness of any one or more of the first sublayer 291, the second sublayer 292, or the third sublayer 293 in any structure 290 of the structure 297 is less than or equal to 50 nm, such as less than or equal to 40 nm, 30 nm, 20 nm, 15 nm, 10 nm, or 5 nm. In some embodiments which may be combined with other embodiments, a morphology of any one or more of the first sublayer 291, the second sublayer 292, or the third sublayer 293 in any structure 290 of the structure 297 changes with increasing thickness.

In some embodiments, it is contemplated that the coating 200 may be repaired. In an example, the sealing layer 280 is removed from the metal body 102 of the chamber component, such as by an ultrasonic cleaning system or a plasma cleaning tool, to expose the pre-existing underlying thermal barrier layer 220. Then, a new sealing layer 280 is deposited onto the pre-existing underlying thermal barrier layer 220.

In another example, weakened (or otherwise compromised) portions of the coating 200 may be removed from the metal body 102 of the chamber component, such as by a mechanical or chemical mechanical grinding tool. A new bond layer 210 may be applied to any exposed surface 104 of the metal body 102. Where a portion of a pre-existing thermal barrier layer 220 may be remaining, the new bond layer 210 may be prevented from contacting the pre-existing thermal barrier layer 220 by masking. Alternatively, the new bond layer 210 may be applied to the pre-existing thermal barrier layer 220 to serve as a metallic sublayer of a metal-ceramic laminate. In some embodiments which may be combined with other embodiments, such as in the absence of there being an exposed surface 104 of the metal body 102, the new bond layer 210 is omitted. A new thermal barrier layer 220 is applied. In some embodiments which may be combined with other embodiments, the new thermal barrier layer 220 is applied over an existing sealing layer 280. A new sealing layer 280 is applied over the new thermal barrier layer 220.

It is contemplated that embodiments of the coating 200 of the present disclosure may provide multiple benefits to the operation of a processing chamber, such as processing chamber 100. One benefit is in providing an insulative barrier to inhibit heat transfer from the processing volume 140 of the processing chamber 100 to the metal body 102 of a chamber component. In an example, without the coating 200, heat dissipation to the walls of the chamber body 170 can cause the edge of a substrate undergoing processing to cool with respect to the center of the substrate. Such a temperature non-uniformity can adversely affect the quantity and quality of chemical deposition at the edge of the substrate, which can be detrimental to product yield from the substrate. However, a coating 200 of the present disclosure, when applied to the interior walls of the chamber body 170, hinders heat transfer to the chamber body 170, promotes a more uniform substrate temperature, and mitigates the above problems. A further benefit is that the coating 200 assists in substrate temperature management while saving an operator expenses such as costs involved in providing additional heating to the substrate.

Another benefit of embodiments of the coating 200 of the present disclosure is to protect the metal body 102 of a chamber component from corrosion, such as corrosion caused by cleaning gases and/or processing gases. In an example, certain halogen cleaning gases (such as chlorine) may be applied more cost-effectively than other cleaning gases (such as hydrochloric acid) to the processing chamber 100, but the walls of the chamber body 170 are more susceptible to corrosion by the halogen cleaning gases. Such vulnerability to corrosion is acute for a chamber body 170 made of a stainless steel, such as 316L. Conventional thermal barrier coatings do not provide corrosion protection because (i) typically, the bond layers of such conventional coatings do not form a thermally grown oxide layer when used in a processing environment, and (ii) the open porosity of the thermal barrier layers of such conventional coatings provides pathways for gases (such as the cleaning gases) to contact the unprotected bond layers and the underlying metal body of the chamber wall.

In contrast, a bond layer 210 of a coating 200 of the present disclosure may be selected on the basis of (i) having a greater resistance to corrosion by halogen-containing chemicals than the metal body 102 of the chamber component (such as the walls of the chamber body 170), and (ii) having such corrosion resistance despite not forming a thermally grown oxide layer when used in a processing environment. Furthermore, a sealing layer 280 of a coating 200 of the present disclosure hinders the passage of gases into the thermal barrier layer 220 while being resistant to attack from the cleaning gases. Gases, such as the cleaning gases, are deterred from migrating to, and contacting, the metal body 102 of the chamber component, which protects the chamber component from corrosion.

An additional benefit of embodiments of the coating 200 of the present disclosure is that by providing protection against corrosion by halogen gases and gaseous halides, cleaning operations can be tailored to suit different processing environments. For example, in some operations, chlorine gas is preferred as a cleaning gas instead of gaseous hydrochloric acid because cleaning with chlorine gas can be effective when performed at a lower temperature than cleaning with gaseous hydrochloric acid. However, the use of chlorine gas can be more detrimental to chamber components, particularly stainless steel components. The corrosion protection afforded by using coatings 200 of the present disclosure facilitates the use of chlorine gas for cleaning, and provides the benefits of reduced cycle times and lower heating costs compared to cleaning operations using gaseous hydrochloric acid.

A further benefit of embodiments of the coating 200 of the present disclosure is the reduction of contamination of a substrate compared to other processing environments that do not incorporate the coating 200 of the present disclosure. When a chamber component, such as the wall of the chamber body 170, suffers corrosion, particles of metal and corrosion products from the chamber component may become released into the processing volume 140 during a processing operation, and may be deposited on a substrate, which contaminates the structure being formed on substrate. Such contamination is detrimental to product quality and product yield from the substrate.

However, the corrosion protection provided by coatings 200 of the present disclosure hinders the generation of particles of metal and corrosion products from the coated chamber component, which reduces contamination of a substrate undergoing processing.

It is contemplated that elements and features of any one disclosed embodiment may be beneficially incorporated in one or more other embodiments. While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber component comprising:
a metal body;
a metallic bond layer deposited on a surface of the metal body;
a thermal barrier layer deposited on the bond layer; and
a substantially non-porous ceramic sealing layer deposited on the thermal barrier layer.

2. The substrate processing chamber component of claim 1, wherein the bond layer comprises at least one of pure nickel, pure titanium, a cobalt-based alloy, an iron-based alloy, a nickel-based alloy, a titanium-based alloy, or a composite of ceramic particulates distributed in a metal matrix.

3. The substrate processing chamber component of claim 1, wherein the bond layer has a coefficient of thermal expansion less than a coefficient of thermal expansion of the metal body, and greater than or equal to a coefficient of thermal expansion of the thermal barrier layer.

4. The substrate processing chamber component of claim 1, wherein:
the thermal barrier layer comprises a single phase ceramic structure including a primary ceramic doped with a secondary ceramic;
a proportion of the secondary ceramic varies from a first magnitude at a first location to a second magnitude at a second location;
the second proportion is lower than the first proportion; and
the first and second locations differ in proximity to the surface of the metal body.

5. The substrate processing chamber component of claim 1, wherein:
the thermal barrier layer comprises one or more pairs of sublayers, each pair of sublayers comprising:
a first sublayer comprising a first ceramic; and
a second sublayer comprising a second ceramic; and
the first ceramic differs from the second ceramic in at least one of:
chemical composition;
porosity;
magnitude of open porosity; or
morphology.

6. The substrate processing chamber component of claim 1, wherein the thermal barrier layer comprises:
a first sublayer comprising a first ceramic;
a second sublayer comprising a first metal on top of the first sublayer; and
a third sublayer comprising a second ceramic on top of the second sublayer.

7. The substrate processing chamber component of claim 6, wherein the first ceramic and the second ceramic have the same chemical composition.

8. The substrate processing chamber component of claim 6, wherein the first ceramic differs from the second ceramic in at least one of:
chemical composition;
porosity;
magnitude of open porosity; or
morphology.

9. The substrate processing chamber component of claim 6, wherein the thermal barrier layer further comprises one or more pairs of additional sublayers on top of the third sublayer, each pair of additional sublayers comprising:
a fourth sublayer comprising a second metal; and
a fifth sublayer comprising a third ceramic on top of the fourth sublayer.

10. The substrate processing chamber component of claim 1, wherein the thermal barrier layer comprises at least one of a metal oxide, a metal nitride, a metal oxynitride, or a metal oxycarbide.

11. The substrate processing chamber component of claim 1, wherein the ceramic sealing layer comprises at least one of a metal oxide, a metal fluoride, or a metal oxyfluoride.

12. The substrate processing chamber component of claim 11, wherein the ceramic sealing layer comprises at least one of silica, hafnia, zirconia, yttria, magnesium fluoride, yttrium fluoride, lanthanum fluoride, or yttrium oxyfluoride.

13. The substrate processing chamber component of claim 1, wherein the ceramic sealing layer comprises:
a first sublayer comprising a first ceramic; and
a second sublayer comprising a second ceramic of a different chemical composition to the first ceramic.

14. The substrate processing chamber component of claim 13, wherein the ceramic sealing layer further comprises a third sublayer comprising the first ceramic deposited on the second sublayer.

15. A substrate processing chamber component comprising:
a body comprising a stainless steel;
a metallic bond layer of a first thickness deposited on a surface of the body, the bond layer having a corrosion resistance to halogen-containing chemicals greater than a corrosion resistance of the body to halogen-containing chemicals;
a thermal barrier layer of a second thickness deposited on the bond layer, the second thickness greater than the first thickness; and
a substantially non-porous ceramic sealing layer of a third thickness deposited on the thermal barrier layer, the third thickness less than the first thickness.

16. The substrate processing chamber component of claim 15, wherein the thermal barrier layer has an overall thermal conductivity of less than or equal to 20 W/m·K.

17. The substrate processing chamber component of claim 15, wherein the third thickness is from 0.05 microns to 10 microns.

18. The substrate processing chamber component of claim 15, wherein the ceramic sealing layer resists corrosion by halogen-containing chemicals.

19. The substrate processing chamber component of claim 15, wherein the ceramic sealing layer is conformally deposited on the thermal barrier layer by one of atomic layer deposition or ion beam sputtering.

20. A substrate processing chamber component comprising:
a metal body;
a metallic bond layer deposited on a surface of the metal body;
a thermal barrier layer deposited on the bond layer; and
a ceramic sealing layer deposited on the thermal barrier layer, the ceramic sealing layer comprising:
a first sublayer comprising a first ceramic;
a second sublayer comprising a second ceramic; and
a third sublayer comprising a third ceramic;
wherein the second ceramic is of a different chemical composition to the first and third ceramics.
